(19) United States
(12) Patent Application Publication
(10) Pub. No.: US 2015/0323615 A1
(43) Pub. Date: Nov. 12, 2015

(54) WIDE DYNAMIC RANGE MAGNETOMETER

(71) Applicant: INSTITUTE OF GEOLOGICAL AND NUCLEAR SCIENCES LIMITED, Avalon, Lower Hutt (NZ)

(72) Inventors: John Vedamuthu Kennedy, Lower Hutt (NZ); Jerome Leveneur, Lower Hutt (NZ); Grant Victor McLelland Williams, Upper Hutt (NZ)

(21) Appl. No.: 14/652,430

(22) PCT Filed: Dec. 17, 2013
(86) PCT No.: PCT/IB2013/061007

§ 371 Date: Jun. 15, 2015

(30) Foreign Application Priority Data
Dec. 17, 2012 (NZ) 604687

(51) Int. Cl. G01R 33/09; G01R 33/07

(52) U.S. Cl. CPC G01R 33/093; G01R 33/07

(57) ABSTRACT

A magnetometer 100, for determining an external magnetic field, comprises a magnetoresistive material forming, an electrode arrangement 104, and a processor. A resistive response of the magnetoresistive material comprises a decreasing response for a first range of increasing applied external magnetic fields, and an increasing response for a second range of increasing applied external magnetic fields. The electrode arrangement 104 measures the resistive response of the magnetoresistive material to the applied external magnetic field. The processor is configured to determine if the external magnetic field applied to the magnetoresistive material is in the first range or in the second range. The processor is configured to determine the external magnetic field based at least partly on the resistive response of the magnetoresistive material to the external magnetic field and whether the external magnetic field is in the first range or in the second range.

The present invention relates generally to methods, systems and apparatus for performing wide dynamic range magnetic field measurements, and the application of such methods, systems and apparatus in, for example, magneto-electronic devices such as magnetic field sensors and current sensors.

### BACKGROUND

While many technologies are currently available for magnetic field measurements, there are very few magnetometer device options to measure reliably both low magnetic fields (<1 μT) and high magnetic field (up to several tens of Teslas). In most cases, a magnetometer useful for measuring low magnetic fields cannot be used to measure reliably high magnetic fields, and vice versa. Such measurement is required for several applications that include non-contact current measurements in uninterruptible power systems and other devices.

Induction search coils are the most versatile technology as the coils can be designed specifically for different applications. However, this technology can only measure AC magnetic fields and the sensitivity decreases as the size is reduced. Some applications, such as power control for batteries, ion transport and accelerator systems, require the ability to measure precisely a magnetic field, either from current flowing through a wire or an electromagnet, over a wide range of magnetic fields. At present, this can only be achieved by using several complementary sensors.

Precise magnetic field measurements are necessary in a wide range of fields and applications ranging from navigation to accelerator technology and materials science. Such measurements are also required when there is a need to measure current flowing through a conductor without contacts like, for example for controlling batteries, solar cells or fuel cells. For these and other applications, the dimensions of the sensors are limited. Many different technologies have been developed based on different physical principles, such as electromagnetic induction, Hall effect, nuclear precession, Faraday rotation, Superconducting Quantum Interference Device (SQUID), magnetoresistance, giant magnetoimpedance, and fluxgates. Excellent sensitivities were obtained in various magnetic field ranges. However, there are challenges in using a specific magnetic sensor for measuring a wide range of magnetic fields (from nano Teslas to tens of Teslas). For example, Giant Magnetoresistance (GMR) and Anisotropic Magnetoresistance (AMR) sensors are small and can measure small magnetic fields but the devices are limited to ˜50 mT due to saturation of the magnetic material. SQUIDs are also small but they are expensive and sensors utilising this technology are not used to measure large fields. Nuclear precession is also expensive, cannot be miniaturized and they are not capable of measuring small magnetic fields. Bulk Hall effect sensors are the most common magnetic sensor and can be miniaturised, but they are not capable of measuring small magnetic fields. 2D electron gas Hall effect sensors are more sensitive than bulk Hall effect sensors (by a factor of ˜10) but they experience nonlinearity at moderate fields.

Large magnetoresistors can provide an excellent method to measure a wide range of magnetic fields. Indeed, AMR, magnetic tunnelling junction (MTJ), and GMR can probe low magnetic fields (down to several nano Teslas) with high sensitivity. However, saturation of the magnetic material limits their use to fields of less than ˜b 0.1 T. Furthermore, they suffer from hysteresis and, hence, they can display a large variation in sensitivity if they are not operated at fields far below the saturation field. Other magnetoresistance types include avalanche breakdown, spin injection magnetoresistance, and geometrical magnetoresistance. Materials displaying one of these magnetoresistance types can be used to measure high magnetic fields (>0.5 T) but they are not sensitive enough to measure small magnetic fields (<0.1 T). For example, nanostructured materials such as iron (Fe) nanoparticles on a silicon dioxide (SiO₂) substrate with a wide electrode gap have a large positive magnetoresistance. Relatively large magnetoresistances have also been observed in pressed iron (II, III) oxide (Fe₃O₄) nanopowders. However, in this case, the magnetoresistance arises from spin-tunnelling and the effects of near-interface magnetic disorder and spin scattering at and near interface boundaries means that they cannot be used to measure small magnetic fields. Nanogranular Fe:Al₂O₃ thin films have shown large positive magnetoresistances with linear behaviour at high field. Compounds that display magnetoresistance can be used to measure the magnetic field but no single technology spans a wide range from small to high magnetic fields.

Accordingly, it is an object of the present invention to overcome the disadvantages of the above mentioned systems and to provide a magnetic sensor with a wide dynamic range; and/or to at least provide with a useful choice.

### SUMMARY OF THE INVENTION

In accordance with an aspect of the present invention, there is provided a magnetometer for determining an external magnetic field, the magnetometer comprising:
a magnetoresistive material that has a resistive response when the external magnetic field is applied to the magnetoresistive material, the resistive response comprising a decreasing response when a first range of increasing external magnetic fields is applied, and an increasing response when a second range of increasing external magnetic fields is applied; and
an electrode arrangement coupled to the magnetoresistive material that measures the resistive response of the magnetoresistive material to the external magnetic field applied to the magnetoresistive material; and
one or more processors, wherein at least one of the one or more processors is configured to determine if the external magnetic field applied to the magnetoresistive material is in the first range or in the second range; and wherein at least one of the one or more processors is configured to determine the external magnetic field based at least partly on the resistive response of the magnetoresistive material to the external magnetic field and whether the external magnetic field is in the first range or in the second range.

In an embodiment, the magnetoresistive material displays superparamagnetic behaviour where there is negligible magnetic remanence when a large applied magnetic field is reduced to zero.

In an embodiment, the magnetoresistive material comprises nanoparticles, and the material exhibits electron spin polarisation for negative magnetoresistances, which arises from spin tunnelling between nanoparticles over a range of operating temperatures. In an embodiment, the magnetoresistive material comprises nanoparticles chosen from the group consisting of iron, nickel, cobalt, their alloys and oxides, and mixtures thereof showing ferromagnetic behaviour at room temperature. In an embodiment, the magnetoresistive material comprises nanoparticles of a ferromagnetic ferrite. In an embodiment, the ferromagnetic ferrite is chosen from the group consisting of ZnFe₂O₄, BaFe₁₂O₉, and Ni_{0.5}Zn_{0.5}Fe₂O₄.

In another embodiment, the magnetometer comprises a thin film, which comprises the magnetoresistive material. In one embodiment, the nanoparticles are synthesised on or embedded in a surface of a substrate of a thin film. In an embodiment, the thin film comprises silicon dioxide and iron nanoparticles. In an embodiment, the magnetoresistive material contains surface iron (Fe) nanoclusters on silicon dioxide (SiO₂) made by ion implantation and electron beam annealing.

In an additional or alternative embodiment, the magnetometer comprises stacks of thin films, thick films, bulk nano-composite and/or pressed powders, which comprise the magnetoresistive material.

In an embodiment, the magnetoresistive material is a composite containing electronic spin-polarized nanoparticles and non-metallic nanoparticles embedded in a semiconducting matrix. Negative spin-dependent tunnelling at low fields between electronic spin-polarized nanoparticles competes with positive geometric magnetoresistence from the non-metallic nanoparticles in the semiconducting matrix. The net result is a negative magnetoresistence for low fields and a magnetoresistence that increases with increasing magnetic field for high fields. In an embodiment, the electronic spin-polarized nanoparticles are iron (II, III) oxide (Fe₃O₄). In one embodiment, the non-metallic nanoparticles are silver (Ag). In an embodiment, the semiconducting matrix is aluminium oxide (Al₂O₃).

In an embodiment, the electrode arrangement comprises two electrodes. In an alternative embodiment, the electrode arrangement comprises four electrodes.

In an embodiment, the magnetometer comprises a Hall effect sensor that is in electrical communication with at least one of the one or more processors. In an embodiment, the Hall effect sensor is physically separate from the magnetoresistive material. In an alternative embodiment, the Hall effect sensor is integrated with the magnetoresistive material. In an embodiment, the Hall effect sensor is configured to generate a voltage in response to the external magnetic field applied to the magnetoresistive material. In an embodiment, the at least one processor is configured to determine that the external magnetic field is in the first range when the voltage generated by the Hall effect sensor is less than a threshold, and that the external magnetic field is in the second range when the voltage generated by the Hall effect sensor exceeds a threshold. In an alternative embodiment, the at least one processor is configured to determine that the external magnetic field is in the second range when the voltage generated by the Hall effect sensor is less than a threshold, and that the external magnetic field is in the first range when the voltage generated by the Hall effect sensor exceeds a threshold.

In an embodiment, the magnetoresistive material has a non-ohmic property, which is a property where a range of current through the magnetoresistive material is a non-linear function of a voltage applied across the magnetoresistive material. In an embodiment, the at least one of the one or more processors is configured to determine a non-ohmic signal from the magnetoresistive material, wherein the at least one processor is configured to use the non-ohmic signal to determine if the external magnetic field applied to the magnetoresistive material is in the first range or in the second range. In an embodiment, the at least one processor is configured to determine the external magnetic field based at least partly on the difference in the voltage across the magnetoresistive material at two different currents. In an alternative embodiment, the at least one processor is configured to determine the external magnetic field based at least partly on an AC current component that is applied to the magnetoresistive material, which leads to an AC voltage. In an embodiment, a first voltage V₁ is measured using the electrode arrangement for a first current I₁, and a second voltage V₂ is measured using the electrode arrangement for a second current I₂. In an embodiment, the at least one processor is configured to determine a switching field from the non-ohmic properties of the magnetoresistive material. In an embodiment, the at least one processor is configured to calculate a difference between magnetoresistances ΔMR when the first and second currents are applied using the following equation:

ΔMR=V₁(B)/V₁(0)−V₂(B)/V₂(0)

where V₁ and V₂ are the measured voltages for currents of I₁ and I₂, respectively. V₁(B) and V₂(B) are the measured voltages when the external magnetic field B is applied to the magnetoresistive material, and V₁(0) and V₂(0) are the measured voltages when no external magnetic field is applied to the magnetoresistive material.

In an embodiment, when the difference between magnetoresistances ΔMR is greater than a threshold ΔMR_{Switch}, the at least one processor is configured to determine that the external magnetic field is in the second range of magnetic fields, and when the difference between magnetoresistances ΔMR is less than or equal to a threshold ΔMR_{Switch}, the at least one processor is configured to determine that the external magnetic field is in the first range of magnetic fields. In an alternative embodiment, when the difference between magnetoresistances ΔMR is greater than a threshold ΔMR_{Switch}, the at least one processor is configured to determine that the external magnetic field is in the first range of magnetic fields, and when the difference between magnetoresistances ΔMR is less than or equal to a threshold ΔMR_{Switch}, the at least one processor is configured to determine that the external magnetic field is in the second range of magnetic fields.

In an embodiment, a control magnetic source is adapted to apply an AC magnetic field to the magnetoresistive material at a first frequency that interacts with the external magnetic field to create a resulting voltage with an AC component across the magnetoresistive material, wherein the at least one processor is configured to determine if the external magnetic field applied to the magnetoresistive material is in the first range or in the second range based on the AC component. In an embodiment, the magnetometer comprises the control magnetic source. In an embodiment, the AC magnetic field is a small AC magnetic field. In an embodiment, the first frequency is chosen so that the first frequency is different from the frequency range of the external magnetic field to be determined. In an embodiment, where the external magnetic field is a DC magnetic field, the first frequency is greater than about 1 Hz, preferably greater than about 25 Hz, and preferably less than about 1 MHz. In an embodiment, where the external magnetic field is an AC magnetic field, the first frequency is between about 1 Hz and about 1 MHz, and preferably between about 50 Hz and about 500 kHz. In an embodiment, the first frequency is at least about twice the value of a measured frequency range of the external magnetic field. For example, if the user wants to measure magnetic fields between 0 and 1 kHz then the frequency f should be greater than 1 kHz and preferably at least about 2 kHz. In an embodiment, the AC magnetic field is filtered out using a frequency filter. In an embodiment, the magnetometer comprises a frequency filter configured to filter out a voltage component with the first frequency from the AC component. In an embodiment, the frequency filter is a low pass filter. In an alternative embodiment, the frequency filter is a bandpass filter. In an embodiment, the at least one processor is configured to determine that the external magnetic field is in the first range of magnetic fields when the AC component is more than a threshold, and that the external magnetic field is in the second range of magnetic fields when the AC component is less than a threshold. In an alternative embodiment, the at least one processor is configured to determine that the external magnetic field is in the second range of magnetic fields when the AC component is more than a threshold, and that the external magnetic field is in the first range of magnetic fields when the AC component is less than a threshold.

Where specific integers are mentioned herein which have known equivalents in the art to which this invention relates, such known equivalents are deemed to be incorporated herein as if individually set forth.

In addition, where features or aspects of the invention are described in terms of Markush groups, those persons skilled in the art will appreciate that the invention is also thereby described in terms of any individual member or subgroup of members of the Markush group.

As used herein ‘(s)’ following a noun means the plural and/or singular forms of the noun.

As used herein the term ‘and/or’ means ‘and’ or ‘or’ or both.

The term ‘comprising’ as used in this specification means ‘consisting at least in part of’. When interpreting each statement in this specification that includes the term ‘comprising’, features other than that or those prefaced by the term may also be present. Related terms such as ‘comprise’ and ‘comprises’ are to be interpreted in the same manner.

It is intended that reference to a range of numbers disclosed herein (for example, 1 to 10) also incorporates reference to all rational numbers within that range (for example, 1, 1.1, 2, 3, 3.9, 4, 5, 6, 6.5, 7, 8, 9 and 10) and also any range of rational numbers within that range (for example, 2 to 8, 1.5 to 5.5 and 3.1 to 4.7) and, therefore, all sub-ranges of all ranges expressly disclosed herein are hereby expressly disclosed. These are only examples of what is specifically intended and all possible combinations of numerical values between the lowest value and the highest value enumerated are to be considered to be expressly stated in this application in a similar manner.

In this specification where reference has been made to patent specifications, other external documents, or other sources of information, this is generally for the purpose of providing a context for discussing the features of the invention. Unless specifically stated otherwise, reference to such external documents or such sources of information is not to be construed as an admission that such documents or such sources of information, in any jurisdiction, are prior art or form part of the common general knowledge in the art.

Although the present invention is broadly as defined above, those persons skilled in the art will appreciate that the invention is not limited thereto and that the invention also includes embodiments of which the following description gives examples.

### BRIEF DESCRIPTION OF THE FIGURES

Embodiments of the invention will now be described, by way of non-limiting example, with reference to the Figures in which:

FIG. 1 shows a magnetometer including a Hall effect sensor according to a first embodiment of the invention;

FIG. 2 shows a magnetometer including a Hall effect sensor according to a second embodiment of the present invention;

FIG. 3 shows the magnetoresistive response at two different currents as a function of the external magnetic field applied to a magnetometer of an embodiment of the present invention;

FIG. 4 shows the voltage response of a magnetometer of an embodiment of the present invention as a function of the external magnetic field;

FIG. 5 shows the inversion of the voltage function of FIG. 4;

FIG. 6 shows the voltage response of a Hall effect sensor to external magnetic fields;

FIG. 7 shows a flow chart for determining an external magnetic field using a magnetometer comprising Hall effect sensor according to an embodiment of the present invention;

FIG. 8 shows the difference between the magnetoresistance for the two currents shown in FIG. 3 as a function of the external magnetic field;

FIG. 9 shows a flow chart for determining an external magnetic field using two different currents according to an embodiment of the present invention;

FIG. 10 shows a derivative plot of the voltage across a magnetoresistive material in a magnetometer according to an embodiment of the present invention;

FIG. 11 shows a response of a filter for filtering out the low magnetic field according to an embodiment of the present invention; and

FIG. 12 shows a flow chart for determining an external magnetic field using a small AC magnetic field according to an embodiment of the present invention.

### DETAILED DESCRIPTION OF THE INVENTION

The embodiments of the magnetometer described below are suitable for magnetic field measurements over a wide dynamic magnetic field range. Embodiments of the magnetometer described below have application as a magnetic field sensor and/or as a current sensor, for example.

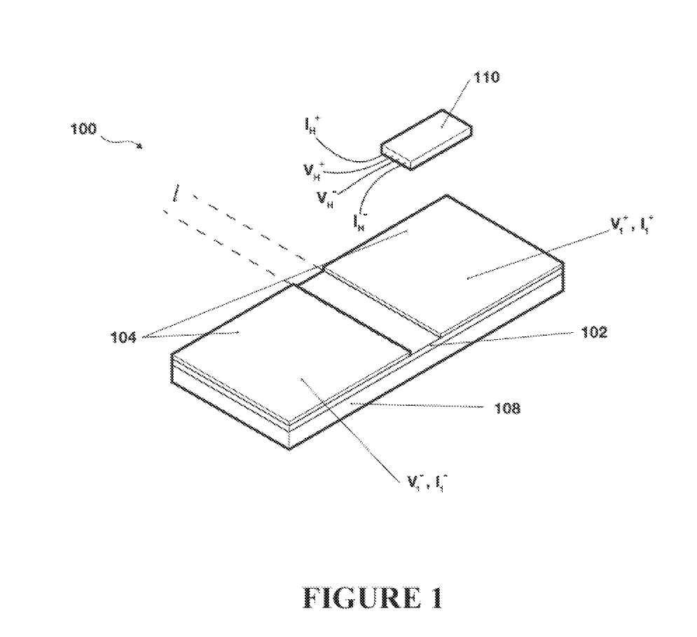

An embodiment of the magnetometer 100 of the present invention is illustrated in FIG. 1. The magnetometer 100 comprises a magnetoresistive material which forms a thin film 102 and two electrodes 104 attached to the magnetoresistive material 102, each electrode 104 being attached to the thin film via a metal film and separate from each other electrode 104 by a gap distance l. In some embodiments, there may be four thin films and four electrodes so that a four terminal measurement is possible.

In the embodiment shown in FIG. 1, the thin film 102 is on a substrate 108. In other embodiments, the magnetometer does not comprise the substrate.

As will be discussed in further detail below, the magnetoresistive material has a non-linear resistive response when the external magnetic field is applied to the magnetoresistive material. In some embodiments of the magnetoresistive material, the resistive response comprises a decreasing response when a first range of increasing external magnetic fields is applied, and an increasing response when a second range of increasing external magnetic fields is applied. As used herein, a ‘decreasing response’ represents a range of magnetic fields within which the slope of a plot of magnetoresistance with respect to magnetic field is negative. An ‘increasing response’ represents a range of magnetic fields within which the slope of a plot of magnetoresistance with respect to magnetic field is positive. According to some embodiments, the magnetic field strength in the first range of magnetic fields comprises a lower range of magnetic field strengths than that in the second range. The magnetic field at which the resistive response changes (from a decreasing response to an increasing response, or vice versa) is described herein as a magnetic switching field B_{switch}.

The magnetometer comprises one or more processors (not shown). At least one of the one or more processors is configured to determine if the external magnetic field applied to the magnetoresistive material is in the first range or in the second range. In the embodiments described below, the at least one processor is configured to determine if the external magnetic field is within a lower range of magnetic fields g_{L} or in an upper range of magnetic fields gᵤ. Further, at least one of the one or more processors is configured to determine the external magnetic field based at least partly on the resistive response of the magnetoresistive material to the external magnetic field and whether the external magnetic field is in the first range or in the second range.

The processor(s) may be any suitable computing device that is capable of executing a set of instructions that specify actions to be carried out. The term ‘computing device’ includes any collection of devices that individually or jointly execute a set or multiple sets of instructions to determine if the external magnetic field applied to the magnetoresistive material is in the first range or in the second range, and to determine the external magnetic field based at least partly on the resistive response of the magnetoresistive material to the external magnetic field and whether the external magnetic field is in the first range or in the second range.

The processor includes or is interfaced to a machine-readable medium on which is stored one or more sets of computer-executable instructions and/or data structures. The instructions implement one or more of the methods of determining the external magnetic field. The instructions may also reside completely or at least partially within the processor during execution. In that case, the processor comprises machine-readable tangible storage media.

The computer-readable medium is described in an example to be a single medium. This term includes a single medium or multiple media. The term ‘computer-readable medium’ should also be taken to include any medium that is capable of storing, encoding or carrying a set of instructions for execution by the processor and that cause the processor to perform the method of determining the external magnetic field. The computer-readable medium is also capable of storing, encoding or carrying data structures used by or associated with the instructions. The term ‘machine readable medium’ includes solid-state memories, non-transitory media, optical media, magnetic media, and carrier wave signals.

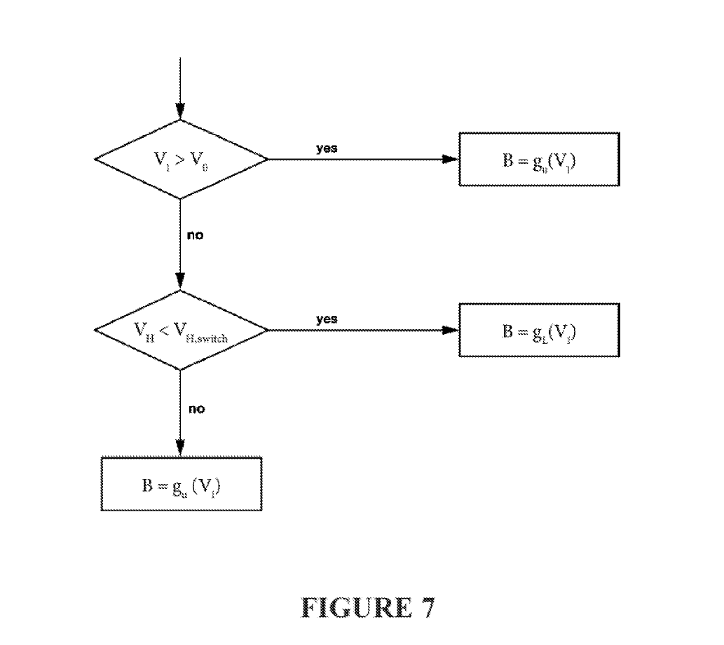

According to the embodiment shown in FIG. 1, the magnetometer comprises a magnetic field sensor 110, which acts as a magnetic field switch, located close to the thin film 102. The magnetic field sensor may for example be a Hall effect sensor. The Hall effect sensor may be a low cost Hall effect sensor. The at least one processor is in electric communication with the Hall effect sensor 110 and uses the measurement from the Hall effect sensor to determine if the external magnetic field is in the first range or in the second range (as shown in FIG. 7).

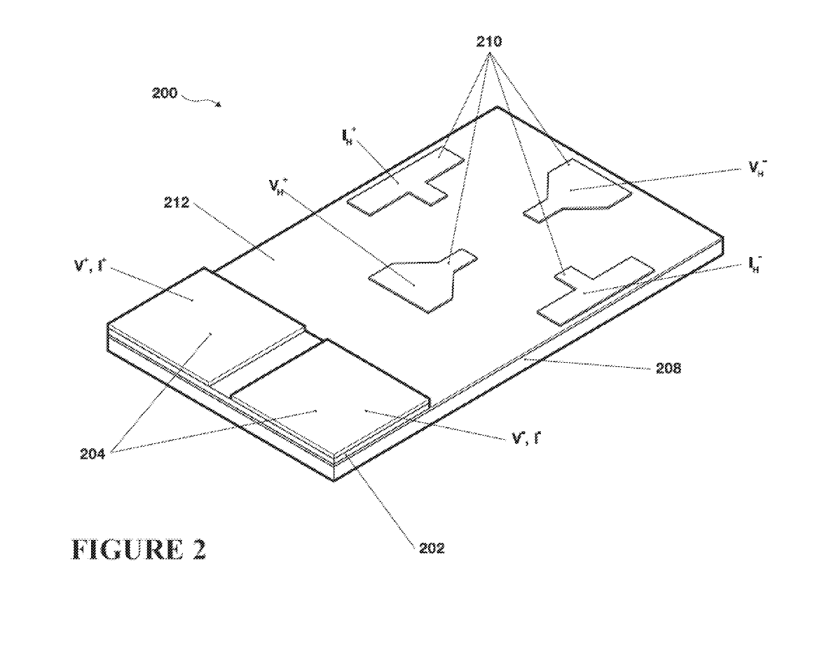

In another embodiment as shown in FIG. 2, the magnetometer 200 comprises a magnetic field switch 210, which is located on the same substrate 208 as the magnetoresistive thin film 202. In the embodiment shown in FIG. 2, the metal electrodes 204 are positioned on the thin film 202 comprising the magnetoresistive material, and the thin film is positioned on a semiconductor film 212, which is itself positioned on the substrate 208.

As with the embodiment described with reference to FIG. 1, in other embodiments of the magnetometer 200, the magnetometer does not comprise a substrate.

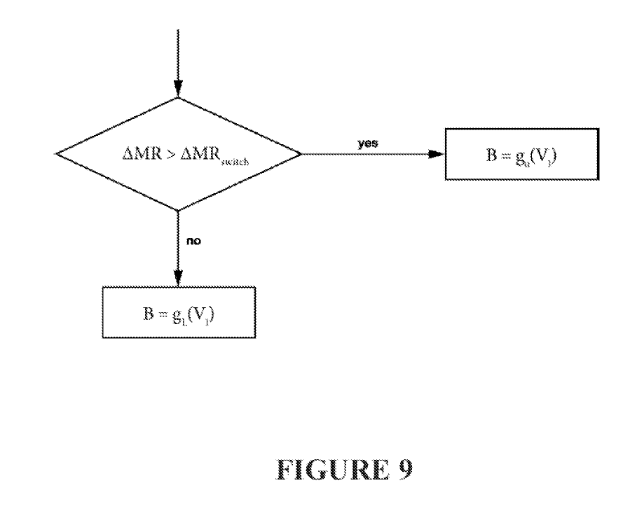

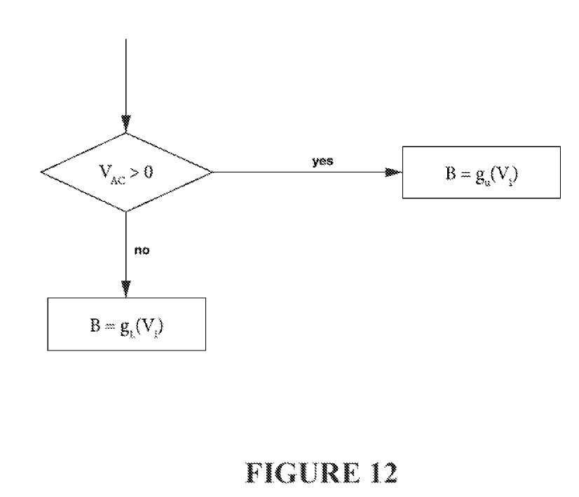

In some embodiments, at least one of the processors is configured to determine the magnetic switching field from the non-ohmic properties of the magnetoresistive film (as shown in FIG. 9) or by applying a small AC magnetic field (as shown in FIG. 12). In these embodiments, a magnetic field switch (such as that described with reference to FIGS. 1 and 2) is not required. If the polarity of the external magnetic field applied to the magnetoresistive material needs to be determined, it can be determined, for example, by applying a bias DC magnetic field to the magnetoresistive material.

The Magnetoresistive Material

The magnetoresistive material has a magnetoresistive property that is measurable in response to an applied external magnetic field. The term ‘magnetoresistive property’ refers to the property of a material having a magnetoresistance that is a function of the applied external magnetic field R(B) where B is the external magnetic field applied to the magnetoresistive material. The corresponding magnetoresistance is defined as MR=[R(B)−R(0)]/R(0) where R(B) is the resistance of the magnetoresistive material when a magnetic field B is applied to the material and R(0) is the resistance when there is no magnetic field applied to the material.

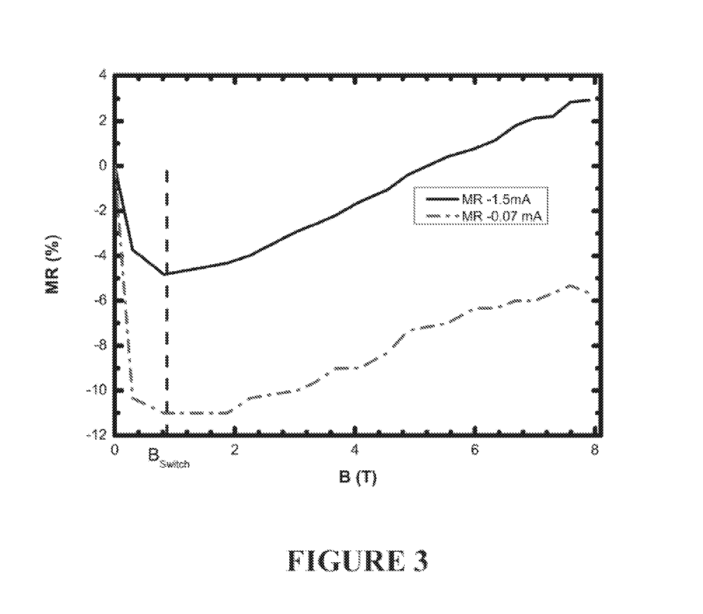

FIG. 3 shows an example of the magnetoresistive response of a magnetoresistive material to an applied magnetic field at two different currents (−0.07 mA and −1.5 mA). To determine the resistance of a magnetoresistive material, a current is applied through the magnetoresistive material so that a voltage can be measured across the material using the electrode arrangement. Thereby, the resistance of the magnetoresistive material can be determined. As used herein, the terms ‘magnetoresistive property’, ‘magnetoresistance’ and ‘resistance’ refer to the resistance of the magnetoresistive material. The magnetoresistance measurements are generally indicative of external magnetic field values in the range of micro Teslas to tens of Teslas depending on the magnetoresistive material. The properties and construction of the thin film comprising the magnetoresistive material will be described in further detail below.

The magnetoresistive material is preferably characterised by:
a magnetoresistive behaviour where the resistance initially decreases and then increases as an increasing magnetic field is applied; and
superparamagnetic behaviour where there is negligible magnetic remanence when a large applied magnetic field is reduced to zero.

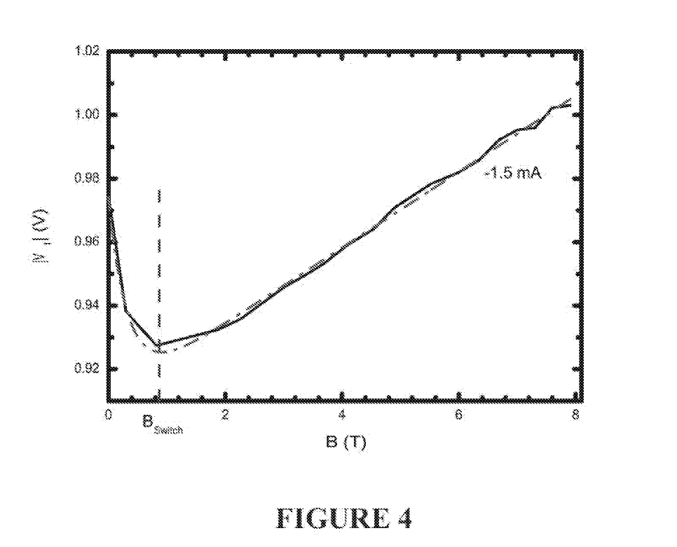

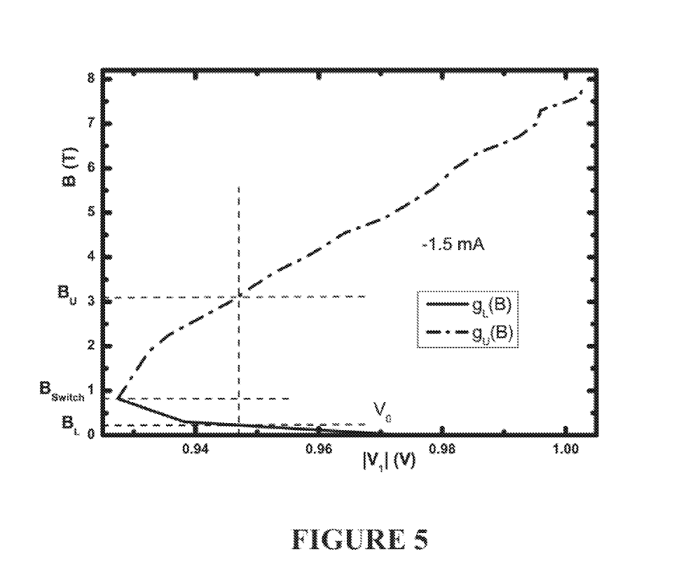

Referring to FIG. 4, the voltage V₁(B) across the magnetoresistive material measured using the electrode arrangement is a function of the applied magnetic field B applied to the magnetoresistive material. V₁(B) initially decreases with increasing external magnetic field B until the magnetic switching field B_{switch}, after which V₁(B) increases with increasing magnetic field. The range of magnetic fields from 0 T to B_{switch} is the lower range of magnetic fields g_{L} while the range of magnetic fields from B_{switch} upwards is the upper range of magnetic fields gᵤ. Thus, for a certain range of magnetic fields a measurement of V₁(B) corresponds to two possible magnetic fields and this depends on whether B is greater or less than B_{switch}, as shown in FIG. 5. The actual magnetic field can be determined by determining if B is greater or less than B_{switch}.

A magnetometer comprising a high permeability superparamagnetic magnetoresistive material has negligible hysteresis, and negligible remnant magnetization. Thus, the magnetometer can be exposed to very high magnetic fields without being damaged or requiring degaussing, which is required for GMR, AMR, and MTJ sensors. The magnetometer can operate without the addition of a bias field for low magnetic field sensing. This is in contrast to GMR and AMR sensors, where a bias field is required for accurate and reproducible measurements of the applied magnetic field. In addition, the changes in the magnetoresistance under an applied magnetic field also allow the measurement of moderate to large magnetic fields, which is not possible with GMR, AMR, and MTJ sensors when they are designed to measure small magnetic fields.

In one embodiment, the magnetoresistive material displays superparamagnetic behaviour where there is negligible magnetic remanence when a large applied magnetic field is reduced to zero. In one embodiment, the magnetoresistive material comprises nanoparticles, and the material exhibits electron spin polarisation for negative magnetoresistances, which arises from spin tunnelling between nanoparticles over a range of operating temperatures. In one embodiment, the magnetoresistive material comprises nanoparticles chosen from the group consisting of iron, nickel, cobalt, their alloys and oxides, and mixtures thereof showing ferromagnetic behaviour at room temperature. In one embodiment, the magnetoresistive material comprises nanoparticles of a ferromagnetic ferrite. In one embodiment, the ferromagnetic ferrite is chosen from the group consisting of ZnFe₂O₄, BaFe₁₂O₉, and Ni_{0.5}Zn_{0.5}Fe₂O₄.

In another embodiment, the magnetometer comprises a thin film, which comprises the magnetoresistive material. In one embodiment, the nanoparticles are synthesised on or embedded in a surface of a substrate of the thin film. In one embodiment, the thin film comprises silicon dioxide and iron nanoparticles.

In some embodiments, the magnetometer may additionally or alternatively comprise stacks of thin films, thick films, bulk nano-composite, and/or pressed powders, which comprise the magnetoresistive material.

In some embodiments of the invention, the magnetoresistive materials are synthesised by means of ion implantation of iron (Fe) in a silicon dioxide (SiO₂) substrate followed by electron beam annealing. In these embodiments, B_{switch} is between 0.1 and 2 T and the detectible field range is from <100 μT to 8 T. In a preferred embodiment B_{switch} is between 0.8 and 1.5 T and the detectible field range is from 20 μT to 8 T.

In some embodiment, and to allow for wide dynamic range magnetoresistance measurements, the gap between the electrodes l is much smaller than the dimensions of the electrode a×b. In one embodiment, l ranges from 0.05 to 0.2 mm, and a and b range from 1 to 4 mm. In some embodiments, the thin film is 80 to 500 nm thick. In preferred embodiments, the thin film is 400 nm thick and the nanostructured region lies on the surface and to a depth of up to 30 nm.

Example Wide Dynamic Range Magnetometers

The description below describes the fabrication of a wide dynamic range magnetometer as shown in FIG. 1.

A magnetic material comprising iron nanoclusters uniformly distributed in a 10 mm×10 mm silicon dioxide on silicon substrate was fabricated using ion implantation and electron beam annealing. The iron atoms were implanted with an energy of 15 keV and a fluence of 1×10¹⁶ ions cm⁻², followed by electron beam annealing at 1000° C. for one hour. From the material, 8 mm×4 mm samples were cut.

Two electrical contacts were fabricated by depositing a 2 nm thick titanium layer followed by a 20 nm thick aluminium layer on both ends of the material using high vacuum vapour deposition. The electrode dimensions were l=0.06 mm and a=b=4 mm. The titanium layer was used to improve the adhesion and electrical contact between the aluminium and the magnetic material. To improve the electrical conductivity between the magnetic material and the contacts, they were annealed at about 300° C. for 30 minutes.

The transducer was tested in a commercially available electron transport measurement tool with a stabilised current generator with various currents and calibrated precise electromagnets. It was subjected to different applied magnetic fields. The magnetic material showed large sensitivity across a wide range of external fields (0 T to 8 T). As shown in FIG. 3 for I=−1.5 mA, the response showed two trends one at low magnetic fields and up to about 0.8 T, the other at high magnetic fields above about 0.8 T to 8 T. FIG. 3 shows the non-ohmic behaviour of the magnetoresistance for I=−1.5 mA and the magnetoresistance for I=−0.07 mA.

An alternative configuration, presented in FIG. 2, includes using a semiconductor substrate 208 such as Si or AsGa, which is covered partially by a nanostructured magnetoresistive thin film 202. The nanostructured thin film may be fabricated by depositing an insulator followed by ion implantation and electron beam annealing in order to form magnetic nanostructures on the surface. The film can be deposited through a mask using standard deposition technique such as chemical vapour deposition, plasma vapour deposition, or ion beam sputter deposition. The bare semiconductor may be used for Hall effect measurements. Four metal contacts 210 in Van der Pauw geometry are deposited on the bare semiconductor and two are deposited on the nanostructured thin film. The same deposition techniques as described above can be used. An excitation current is fed through two opposing contacts (I_{H}⁺, I_{H}⁻) and the voltage is measured across (V_{H}⁺, V_{H}⁻). At a constant excitation current, the Hall effect induces a change of the voltage linear with an external applied magnetic field. Two metal contacts (204) are used to measure the resistivity of the magnetoresistive thin film under an applied magnetic field. The gap and film dimensions are similar to those described above for the embodiment shown in FIG. 1.

The alternative configuration described above may enable determination of the magnetic field with a better degree of spatial accuracy.

Determination of an External Magnetic Field

Using a Hall Effect Sensor

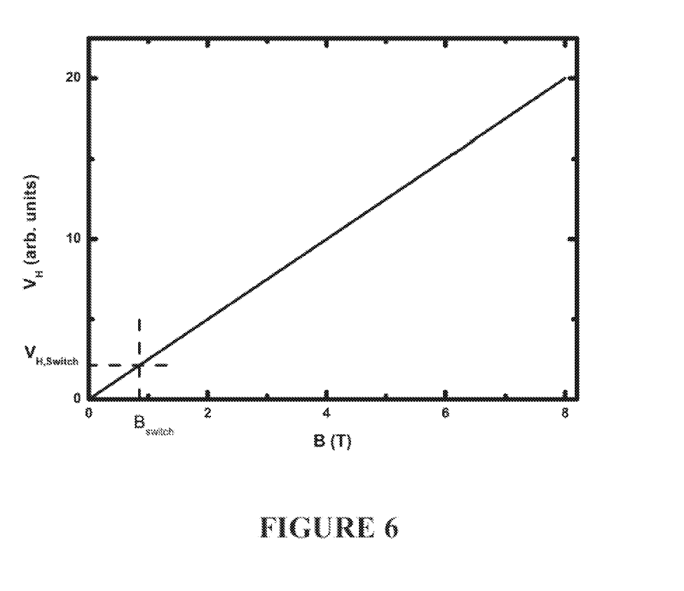

In one embodiment, the magnetometer comprises two discrete sensors (as shown in FIG. 1) or integrated sensors (as shown in FIG. 2). The sensors comprise the magnetoresistive material and the Hall effect sensor. A current I₁ is applied to the thin film electrodes and the voltage V₁(B) is measured using the electrode arrangement. In one embodiment, a current I_{H} is applied to a Hall effect sensor and the voltage V_{H}(B) measured. The external magnetic field can be determined using the voltage V_{H}(B) from the Hall effect sensor that is a linear function of the applied magnetic field as shown in FIG. 6. For low magnetic fields g_{L} , the Hall effect sensor is not sensitive enough to accurately detect the applied magnetic field. If V_{H} is greater than V_{H,switch} (see FIG. 6) then V₁(B) corresponds to the upper magnetic field gᵤ from the V₁(B) curve and vice versa, wherein the upper magnetic field B is the higher of the two magnetic field strengths that give the same magnetoresistance measurements.

The V_{H,switch} threshold can be determined by measuring the magnetoresistance response over the full range of magnetic field. V_{H,Switch} is determined by initial calibration measurements of V₁ as shown in FIG. 4, from which B_{Switch} is also determined. From the Hall effect sensor calibration data shown in FIG. 6, the experimentally determined B_{Switch} can be used to determine V_{H,Switch}.

The flowchart showing the algorithm used by at least one of the processors for determining an external magnetic field using a Hall effect sensor is shown in FIG. 7. The first step of the at least one processor determining if V₁>V₀ determines if V₁(B) is single valued (a value where the magnetic field is substantially high that the voltage does not correspond to a value in the lower magnetic field range), in which case the magnetic field B is in the upper range of magnetic fields, gᵤ(V₁). If V₁(B) is not single valued, the at least one processor is configured to determine if the external magnetic field is within the lower magnetic field range g_{L} or within the upper magnetic field range gᵤ by comparing the voltage from the Hall effect sensor V_{H} to the V_{H,switch} threshold.

Using Non-Ohmic Properties of the Magnetoresistive Material

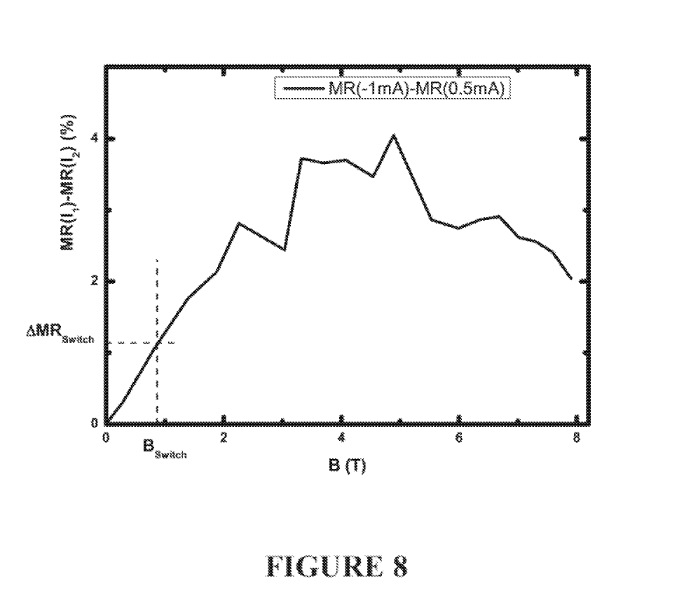

In an alternative embodiment, the magnetometer comprises a thin film magnetoresistive material with the electrode arrangement, and does not comprise a Hall effect sensor. In this case, the at least one of the one or more processors is configured to determine the magnetic field using the non-ohmic properties of the magnetoresistive thin film. In this embodiment, a voltage V₁ is measured for a current I₁, and a voltage V₂ is measured for a current I₂. The voltages are measured using the electrode arrangement. The switching field can be determined from the non-ohmic properties of the film. As shown in FIG. 3, the magnetoresistance can be measured using the applied current. The resultant difference in the magnetoresistance for two different currents, I₁ and I₂ is plotted in FIG. 8 for I₁=−1 mA and I₂=0.5 mA. ΔMR_{Switch} is the magnetoresistance when B=B_{Switch}, which can be determined using a calibration measurement of ΔMR as a function of the external magnetic field, B. Thus, if ΔMR is greater than ΔMR_{Switch} (as shown in FIG. 8) then V₁(B) corresponds to the upper B from the V₁(B) curve and vice versa. ΔMR is easily determined from the measured voltages using the following equation:

ΔMR=V₁(B)/V₁(0)−V₂(B)/V₂(0)

where V₁ and V₂ are the measured voltages for currents of I₁ and I₂, respectively. V₁(B) and V₂(B) are the measured voltages when the external magnetic field B is applied to the magnetoresistive material, and V₁(0) and V₂(0) are the measured voltages when no external magnetic field is applied to the magnetoresistive material.

FIG. 9 shows the flowchart of the algorithm used by at least one of the processors for determining an external magnetic field using the non-ohmic properties of the magnetoresistive material and the voltages at two different currents as shown in FIG. 8. The at least one processor is configured to determine if the external magnetic field is within the lower magnetic field range g_{L} or in the upper magnetic field range gᵤ by comparing the difference in magnetoresistance at the two currents ΔMR to the ΔMR_{switch} threshold.

Using a Separate AC Magnetic Field

In an alternative embodiment, the magnetometer comprises a thin film comprising the magnetoresistive material, and does not comprise a Hall effect sensor. A voltage V₁(I) is measured using the electrode arrangement for a current I₁. The magnetometer comprises a control magnetic field source that is configured to apply a small AC magnetic field Bₘ sin(2nft) where Bₘ is the magnitude, f is the frequency and t is the time. If Bₘ is small then the resultant detected voltage when the magnetic field B₀ is applied will be:

$${{V}_{1} ( {B}_{0} , t ) = V ( {B}_{0} ) + \frac{d V}{d B} \vert}_{{B}_{0}} {B}_{m} Sin ( 2 π f t )$$

and hence the detected AC voltage amplitude will be:

$${{V}_{A C} ( {B}_{0} ) = \frac{d V}{d B} \vert}_{{B}_{0}} {B}_{m} .$$

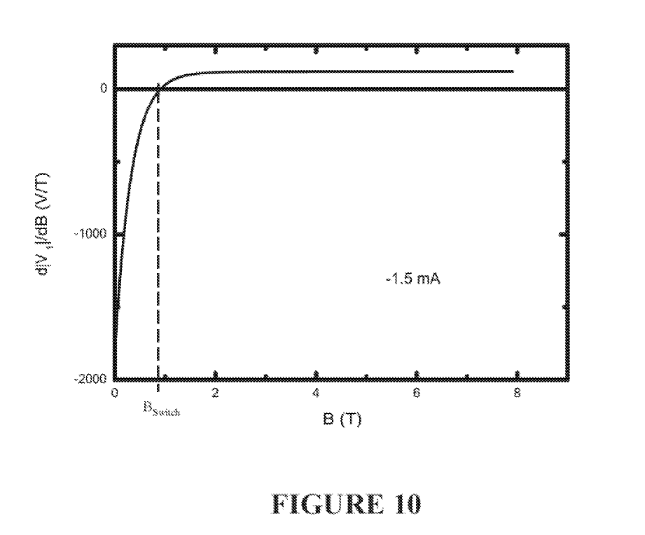

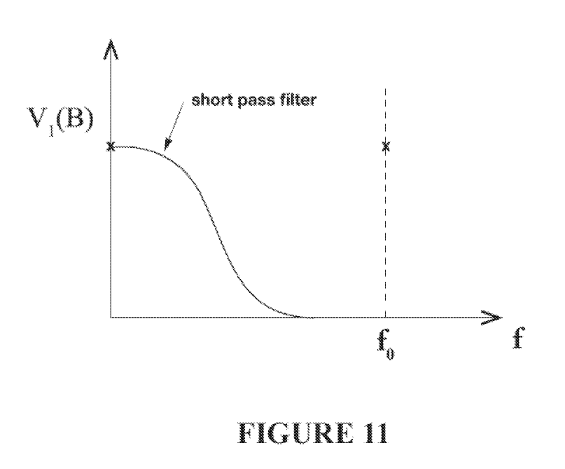

V_{AC} is illustrated in FIG. 10 where it can be seen that B_{switch} can be defined as that magnetic field for which V_{AC}(B₀)=0. The curve in FIG. 10 was obtained from the derivative of a fit to the data in FIG. 4 using a phenomenological fitting function, |V₁|=M₀ exp(−B/T₁)+a₀+a₁B+a₂B² (shown as a dashed curve in FIG. 4). Thus, if V_{AC} is greater than zero then V₁(B) corresponds to the upper B from the V₁(B) curve and vice versa. The AC signal can be removed using a low pass filter as shown in FIG. 11 for example, where only the DC signal remains. According to other embodiments, a bandpass filter can be used to remove the small applied AC signal and f can be chosen so that it is outside the known frequency range of the magnetic field to be detected. For measuring DC magnetic fields, the frequency f should be greater than 1 Hz, preferably greater than 25 Hz. In one embodiment, the frequency is less than about 1 MHz. For measuring AC magnetic fields the frequency f should be between about 1 Hz and about 1 MHz, and preferably between about 50 Hz and about 500 kHz. The frequency f should ideally be outside the measured AC magnetic field frequency range, and preferably at least about twice the value of the measured frequency range. For example, if the user wants to measure magnetic fields between 0 and 1 kHz then the frequency f should be greater than 1 kHz and preferably at least about 2 kHz.

The flowchart of the algorithm used by at least one of the processors for determining an external magnetic field using the derivative of the voltage data in FIG. 10 is shown in FIG. 12. The at least one processor is configured to determine if the external magnetic field is within the lower magnetic field range g_{L} or in the upper magnetic field range gᵤ by determining if V_{AC} is greater or less than zero.

Some embodiments of the magnetometer may use a combination of two or more of the Hall effect sensor, non-ohmic properties of the magnetoresistive material, and the separate AC magnetic field to determine the external magnetic field applied to the magnetometer.

It is not the intention to limit the scope of the invention to the abovementioned examples only. As would be appreciated by a skilled person in the art, many variations are possible without departing from the scope of the invention.

1. A magnetometer for determining an external magnetic field, the magnetometer comprising:
a magnetoresistive material that has a resistive response when the external magnetic field is applied to the magnetoresistive material, the resistive response comprising a decreasing response when a first range of increasing external magnetic fields is applied, and an increasing response when a second range of increasing external magnetic fields is applied; and
an electrode arrangement coupled to the magnetoresistive material that measures the resistive response of the magnetoresistive material to the external magnetic field applied to the magnetoresistive material; and
one or more processors, wherein at least one of the one or more processors is configured to determine if the external magnetic field applied to the magnetoresistive material is in the first range or in the second range, and wherein at least one of the one or more processors is configured to determine the external magnetic field based at least partly on the resistive response of the magnetoresistive material to the external magnetic field and whether the external magnetic field is in the first range or in the second range.

2. The magnetometer of claim 1, wherein the magnetoresistive material displays superparamagnetic behaviour where there is negligible magnetic remanence when a large applied magnetic field is reduced to zero.

3. The magnetometer of claim 1 or 2, wherein the magnetoresistive material comprises nanoparticles, and the material exhibits electron spin polarisation for negative magnetoresistances, which arises from spin tunnelling between nanoparticles over a range of operating temperatures.

4. The magnetometer of claim 3, wherein the magnetoresistive material comprises nanoparticles chosen from the group consisting of iron, nickel, cobalt, their alloys and oxides, and mixtures thereof showing ferromagnetic behaviour at room temperature.

5. The magnetometer of claim 3, wherein the magnetoresistive material comprises nanoparticles of a ferromagnetic ferrite.

6. The magnetometer of claim 5, wherein the ferromagnetic ferrite is chosen from the group consisting of ZnFe₂O₄, BaFe₁₂O₉, and Ni_{0.5}Zn_{0.5}Fe₂O₄.

7. The magnetometer of claim 3 or 4, wherein the nanoparticles are iron (II, III) oxide (Fe₃O₄).

8. The magnetometer of any one of claims 3 to 7, wherein the magnetoresistive material is a composite containing nanoparticles and non-metallic nanoparticles embedded in a semiconducting matrix.

9. The magnetometer of claim 8, wherein the non-metallic nanoparticles are silver (Ag).

10. The magnetometer of claim 8 or 9, wherein the semiconducting matrix is aluminium oxide (Al₂O₃).

11. The magnetometer of any one of claims 3 to 7, wherein the nanoparticles are synthesised on or embedded in a surface of a substrate of a film.

12. The magnetometer of claim 11, wherein the film comprises a silicon dioxide (SiO₂) substrate and iron (Fe) nanoparticles.

13. The magnetometer of claim 12, wherein the magnetoresistive material contains surface iron nanoclusters on silicon dioxide made by ion implantation and electron beam annealing.

14. The magnetometer of claim 1 or 2, comprising stacks of thin films, thick films, bulk nano-composite and/or pressed powders, which comprise the magnetoresistive material.

15. The magnetometer of any one of claims 1 to 14, wherein the electrode arrangement comprises two electrodes.

16. The magnetometer of any one of claims 1 to 15, wherein the electrode arrangement comprises four electrodes.

17. The magnetometer of any one of claims 1 to 16, comprising a Hall effect sensor that is in electrical communication with at least one of the one or more processors.

18. The magnetometer of claim 17, wherein the Hall effect sensor is physically separate from the magnetoresistive material.

19. The magnetometer of claim 17, wherein the Hall effect sensor is integrated with the magnetoresistive material.

20. The magnetometer of any one of claims 17 to 19, wherein the Hall effect sensor is configured to generate a voltage in response to the external magnetic field applied to the magnetoresistive material.

22. The magnetometer of any one of claims 18 to 21, wherein the at least one processor is configured to determine that the external magnetic field is in the first range when the voltage generated by the Hall effect sensor is less than a threshold, and that the external magnetic field is in the second range when the voltage generated by the Hall effect sensor exceeds a threshold.

23. The magnetometer of any one of claims 18 to 21, wherein the at least one processor is configured to determine that the external magnetic field is in the second range when the voltage generated by the Hall effect sensor is less than a threshold, and that the external magnetic field is in the first range when the voltage generated by the Hall effect sensor exceeds a threshold.

24. The magnetometer of any one of claims 1 to 22, wherein the magnetoresistive material has a non-ohmic property, and the at least one of the one or more processors is configured to determine a non-ohmic signal from the magnetoresistive material, wherein the at least one processor is configured to use the non-ohmic signal to determine if the external magnetic field applied to the magnetoresistive material is in the first range or in the second range.

25. The magnetometer of any one of claims 1 to 24, wherein the at least one processor is configured to determine the external magnetic field based at least partly on the difference in the voltage across the magnetoresistive material at two different currents.

26. The magnetometer of any one of claims 1 to 25, wherein the at least one processor is configured to determine the external magnetic field based at least partly on an AC current component that is applied to the magnetoresistive material, which leads to an AC voltage.

27. The magnetometer of any one of claims 1 to 26, wherein a first voltage V₁ is measured using the electrode arrangement for a first current I₁, and a second voltage V₂ is measured using the electrode arrangement for a second current I₂.

28. The magnetometer of any one of claims 27, wherein the at least one processor is configured to calculate a difference between magnetoresistances ΔMR when the first and second currents are applied using the following equation:
ΔMR=V₁(B)/V₁(0)−V₂(B)/V₂(0)
where V₁ and V₂ are the measured voltages for currents of I₁ and I₂, respectively. V₁(B) and V₂(B) are the measured voltages when the external magnetic field B is applied to the magnetoresistive material, and V₁(0) and V₂(0) are the measured voltages when no external magnetic field is applied to the magnetoresistive material.

29. The magnetometer of claim 28, wherein, when the difference between magnetoresistances ΔMR is greater than a threshold ΔMR_{Switch}, the at least one processor is configured to determine that the external magnetic field is in the second range of magnetic fields, and when the difference between magnetoresistances ΔMR is less than or equal to a threshold ΔMR_{Switch}, the at least one processor is configured to determine that the external magnetic field is in the first range of magnetic fields.

30. The magnetometer of claim 28, wherein, when the difference between magnetoresistances ΔMR is greater than a threshold ΔMR_{Switch}, the at least one processor is configured to determine that the external magnetic field is in the first range of magnetic fields, and when the difference between magnetoresistances ΔMR is less than or equal to a threshold ΔMR_{Switch}, the at least one processor is configured to determine that the external magnetic field is in the second range of magnetic fields.

31. The magnetometer of any one of claims 1 to 30, wherein a control magnetic source is adapted to apply an AC magnetic field to the magnetoresistive material at a first frequency that interacts with the external magnetic field to create a resulting voltage with an AC component across the magnetoresistive material, wherein the at least one processor is configured to determine if the external magnetic field applied to the magnetoresistive material is in the first range or in the second range based on the AC component.

32. The magnetometer of claim 31, wherein the first frequency is chosen so that the first frequency is different from the frequency range of the external magnetic field to be determined.

33. The magnetometer of claim 31 or 32, comprising a frequency filter configured to filter out a voltage component with the first frequency from the AC component.

34. The magnetometer of claim 33, wherein the frequency filter is a low pass filter or a bandpass filter.

36. The magnetometer of any one of claims 31 to 35, wherein the at least one processor is configured to determine that the external magnetic field is in the first range of magnetic fields when the AC component is more than a threshold, and that the external magnetic field is in the second range of magnetic fields when the AC component is less than a threshold.

37. The magnetometer of any one of claims 31 to 35, wherein the at least one processor is configured to determine that the external magnetic field is in the second range of magnetic fields when the AC component is more than a threshold, and that the external magnetic field is in the first range of magnetic fields when the AC component is less than a threshold.

38. The magnetometer of any one of claims 31 to 37, wherein the first frequency is at least about twice the value of a measured frequency range of the external magnetic field.
